(19) United States
(12) Patent Application Publication
(10) Pub. No.: US 2009/0080266 A1
(43) Pub. Date: Mar. 26, 2009

(54) DOUBLE DATA RATE (DDR) LOW POWER IDLE MODE THROUGH REFERENCE OFFSET

(76) Inventor: John F. Zumkehr, Orange, CA (US)

Correspondence Address: INTEL CORPORATION;c/o INTELLEVATE, LLC, P.O. BOX 52050, MINNEAPOLIS, MN, 55402, US

(21) Appl. No.: 11/861,090

(22) Filed: Sep. 25, 2007

(51) Int. Cl. G11C 7/00

(52) U.S. Cl. 365/189.09; 365/189.11

(57) ABSTRACT

Embodiments of the invention are generally directed to systems, methods, and apparatuses for a double data rate (DDR) low power idle mode through reference offset. In some embodiments, a host offsets a reference voltage from a termination voltage of a command/address interconnect when the interconnect is tri-stated. Other embodiments are described and claimed.

### TECHNICAL FIELD

Embodiments of the invention generally relate to the field of integrated circuits and, more particularly, to systems, methods and apparatuses for a double data rate (DDR) low power idle mode through reference offset.

### BACKGROUND

Relatively high speed interfaces, such as double data rate (e.g., DDR, DDR2, and DDR3, etc.) interfaces may include receivers that use a voltage reference (VREF). An incoming digital signal is compared with the VREF to determine whether or not the input signal is a logic level zero or a logic level one. The voltage level of the VREF acts as a trip point (or switch point). An input signal with a voltage level above the trip point is a logic level one and an input signal with a voltage level below the trip point is a logic level zero.

The regulators that provide the VREF also typically provide the memory device (e.g., a dynamic random access memory device or DRAM) voltage. The VREF is usually fixed at one-half of the DRAM voltage. This arrangement is premised on the DRAM and host having processes that use similar operating voltages. For example, if both the DRAM and the host are based on processes that use an operating voltage of 1.5 V, than the driver signal is likely to be centered (more or less) on a VREF of 750 mV.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a high-level block diagram illustrating selected aspects of a computing system implemented according to an embodiment of the invention.

FIG. 2 is a circuit diagram illustrating selected aspects of a command/address (CA) input/output (IO) signal architecture, according to an embodiment of the invention.

FIG. 3 is a signal diagram illustrating an offset between a reference voltage and a termination voltage, according to an embodiment of the invention.

FIG. 4 is a flow diagram illustrating selected aspects of a method for a low power idle mode through reference offset, according to an embodiment of the invention.

FIG. 5 is a block diagram illustrating selected aspects of an electronic system according to an embodiment of the invention.

FIG. 6 is a bock diagram illustrating selected aspects of an electronic system according to an alternative embodiment of the invention.

### DETAILED DESCRIPTION

Embodiments of the invention are generally directed to systems, methods, and apparatuses for a double data rate (DDR) low power idle mode through reference offset. Many conventional memory controllers can tri-state the command/address (CA) lines when idle. The power dissipated by the memory devices, however, when the CA lines are idle is not specified. The memory devices typically require the CA signals to be in a valid logic “one” or “zero” state when the CA lines are in a powered idle state. When tri-stated, the CA lines float to the termination voltage which in conventional implementations is equal to the voltage reference (VREF). This places the CA inputs to the memory devices in an invalid logic state whose power is indeterminate. The power dissipated by the memory devices will be much higher than it would be if the CA inputs had a valid state.

As further described below, embodiments of the invention combine tri-stating the CA interconnect with offsetting the VREF from the VTT. In some embodiments, this offset is greater than the DC margin of the CA DRAM inputs which causes the floating CA lines to be in a valid state. This approach helps to ensure that the DRAMs are in the lowest power dissipation state when in a powered state.

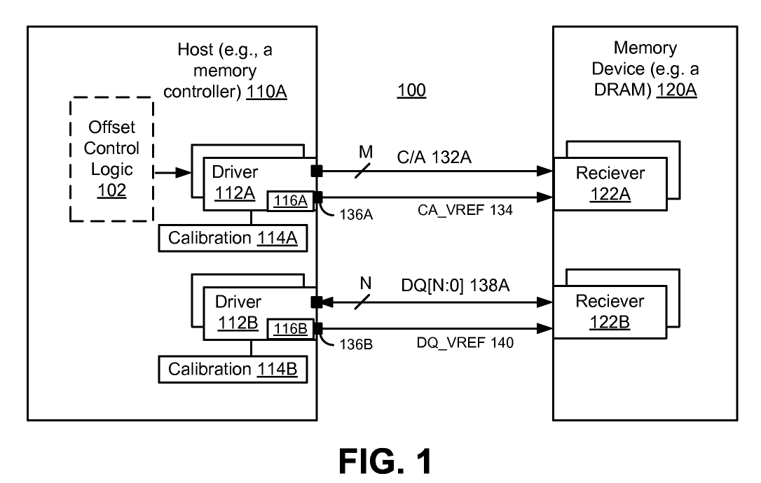

FIG. 1 is a high-level block diagram illustrating selected aspects of a computing system implemented according to an embodiment of the invention. In the illustrated embodiment, system 100 includes host 110 (e.g., a memory controller) and memory device 120 (e.g., a DRAM). In alternative embodiments, system 100 may include more elements, fewer elements, and/or different elements.

Host 110 controls the transfer of data to and from memory device 120. In some embodiments, host 110 is part of the chipset of a computing system (e.g., part of the Northbridge). In alternative embodiments, host 110 is integrated onto the same die as one or more processors. Host 110 includes drivers 112, calibration circuits 114, and offset control logic 102. Drivers 112A are coupled with command/address (CA) interconnect 132 and drivers 112B are coupled with DQ interconnect 138. It is to be appreciated that host 110 may include nearly any number of drivers 112.

In some embodiments, at least some of the drivers 112 include voltage reference (VREF) generation circuitry 116. VREF generation circuitry 116 provides a controllable VREF to memory device 120. Memory device 120 uses the VREF as a reference for the driver signals of one or more associated drivers 112. For example, receiver 122A may use a VREF provided by VREF generation circuitry 116A as a reference for driver signals from driver (or drivers) 112A.

In some embodiments, host 110 includes additional electrical contact(s) 136. Electrical contact(s) 136 provide a contact to couple a VREF to an appropriate interconnect. The term “electrical contact” broadly refers to an externally available contact of an integrated circuit suitable for conveying an electrical signal to an interconnect (e.g., a pin, a pad, a ball, and the like). Electrical contact(s) 136 are referred to as “additional” electrical contacts because conventional hosts do not include an electrical contact to supply VREF to a memory device.

In some embodiments, host 110 may include two or more electrical contacts 136 to supply two or more VREFs to memory device 120. The settings for the VREFs may be independent from one another to support different optimization points for different VREFs. System 100, for example, includes electrical contacts 136A and 136B. Contact 136A couples CA_VREF 134 over command/address interconnect 132A. Similarly, contact 136B couples DQ_VREF 140 over DQ interconnect 138A.

In some embodiments, driver 112 symmetrically drives a signal around an associated VREF. For example, driver 112A symmetrically drives a signal around CA_VREF 134. Similarly, driver 112B symmetrically drives a signal around DQ_VREF 140. A calibration process may be used to calibrate drivers 112 so that the driver signals are symmetrical around a VREF. The calibration process may use calibration circuits 114 to calibrate drivers 112. Calibration circuits 114 may set the pull up and pull down values of driver 112 to determine the characteristics of the driver signal.

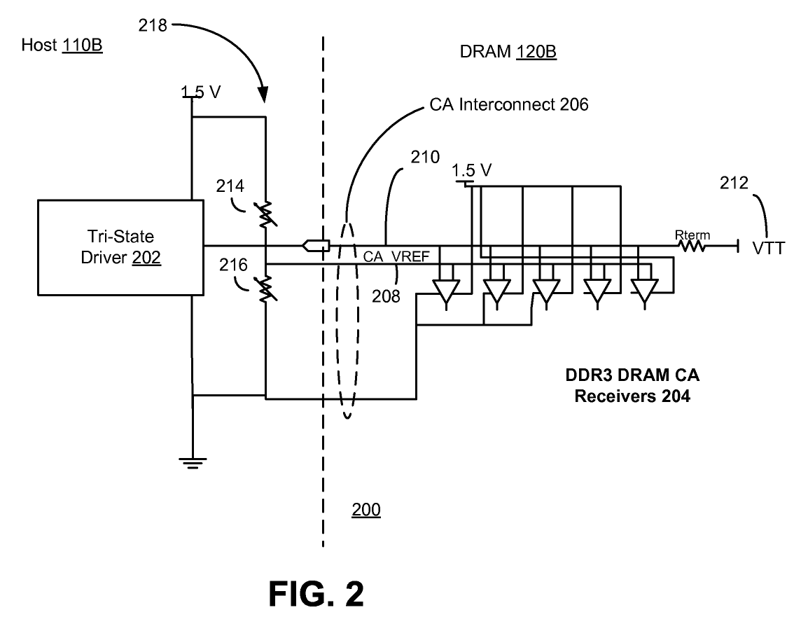

In some embodiments, drivers 112 are tri-state drivers. When tri-stating an interconnect (e.g., CA interconnect 132Aa), it is typically desirable to reduce the power consumed by the interconnect. Thus, when tri-stating the interconnect, drivers 112 no longer pull up or pull down. In conventional systems, the interconnect floats to the VTT voltage (e.g., VTT 212, shown in FIG. 2) when the interconnect is tri-stated.

In some embodiments, CA_VREF 134 is offset from the VTT used by receiver 122A (e.g., VTT 212, shown in FIG. 2). This offset enables system 100 to operate in a low power mode when, for example, CA interconnect 132 is idle (e.g., tri-stated). The power savings may include dynamic and static components. The dynamic component is related to the noise present in the operational amplifiers (op amps) on either side of the interconnect that will dissipate power as the receiver switches in response to the noise. The static component is related to the fact that many IO op amps burn more power when the interconnect is near the midpoint of its operating voltage.

In some embodiments, CA_VREF 134 is controllable and the offset is implemented by moving CA_VREF 134 away from (either above or below) VTT. In other embodiments, VTT is controllable and the offset is implemented by moving VTT away from (either above or below) CA_VREF 134.

In some embodiments, the offset may be performed dynamically. For example, CA_VREF 134 may be dynamically offset from VTT when driver 112A tri-states CA interconnect 132A. Similarly, VTT may be dynamically offset from CA_VREF 134 when driver 112A tri-states CA interconnect 132A. In some embodiments, offset control logic 102 controls the dynamic application of the offset.

In alternative embodiments, the offset may be applied statically. For example, CA_VREF 134 may be statically set to the memory interface voltage (VDDQ) divided by 2 (or another value) and VTT may be statically offset from CA_VREF 134. Alternatively, the VTT may be statically set to VDDQ/2 (or another value) and CA_VREF 134 may be offset from VTT. In some embodiments, if the offset is performed statically, then drivers 112A symmetrically drive signals around the value of CA_VREF 134. Calibration circuits 114A may set the pull up and pull down values of driver 112A to symmetrically drive signals around the value of CA_VREF 134.

Memory device 120 provides, at least in part, the system main memory for system 100. In some embodiments, memory device 120 is a DDR DRAM (e.g., a DDR3 DRAM). Memory device 120 includes, inter alia, receivers 122 to receive signals from host 110. Memory device 120 may be one of a number of memory devices on a memory module. Alternatively, memory device 120 may be attached to a main system circuit board (not shown) for computing system 100.

Command/Address (CA) lanes 132 provide a plurality of lanes for sending commands and addresses to memory device 120. DQ lanes 138 provide a bi-directional read/write data interconnect (or data bus). In alternative embodiments, DQ lanes 138 may be unidirectional. For ease of description, system 100 is illustrated as having M CA lanes and N DQ lanes. It is to be appreciated that the values M and N depend on the implementation details of a particular computing system.

In some embodiments, the power saving benefits of offsetting VREF from VTT are realized on CA interconnect 132A but not on DQ interconnect 138. The reason for this is that host 110 knows when to expect data from memory device 120. Since it knows when to expect data, it can turn the host-side receivers on and off as needed. In contrast, receivers 122A are generally on to minimize latency on CA interconnect 132A.

FIG. 2 is a circuit diagram illustrating selected aspects of a command/address (CA) input/output (IO) signal architecture, according to an embodiment of the invention. System 200 includes tri-state driver 202 and DRAM CA receivers 204 coupled together via CA interconnect 206. For ease of description, only a single driver 202 is shown. In addition, only a portion of CA interconnect 206 is shown. It is to be appreciated that a host (e.g., host 110) may have nearly any number of CA drivers 202. In addition, CA interconnect 206 may include nearly any number of bit lanes, signal lines, electrical contacts, and the like. In alternative embodiments, system 200 may include more elements, fewer elements, and/or different elements.

In conventional systems, a VREF for the DRAM receivers is typically provided by the same regulator that provides the receiver operating voltage and is typically set to one-half of the receiver operating voltage (or 750 mV in the illustrated example). In other conventional systems, a resistor-divider network (e.g., on the memory module) may provide the receiver operating voltage. In conventional systems, the CA driver typically operates at substantially the same operating voltage as the DRAM receivers. The driver signal, in conventional systems, is typically centered on one-half of its operating voltage which is substantially equal to one-half the receiver operating voltage (VDDQ/2).

Unlike conventional systems, in some embodiments, CA_VREF 208 is offset from VTT 212. For example, VTT 212 may be set to a conventional value (such as VDDQ/2) and CA_VREF 208 may be offset (above or below) from that value. Alternatively, CA_VREF 208 may be set to a conventional value and VTT 212 may be offset (above or below) from that value. This offset enables system 200 to consume less power than a conventional system because the CA lines (e.g., the lines of CA interconnect 206) remain in a valid state when they are floating (e.g., when CA interconnect 206 is tri-stated).

In some embodiments, the offset may be statically implemented. For example, CA_VREF 208 may be statically offset from VTT 212. Alternatively, VTT 212 may be statically offset from CA_VREF 208.

In alternative embodiments, the offset may be dynamically implemented. For example, CA_VREF 208 may be dynamically changed when CA interconnect 206 is idle (and/or in response to other conditions). Alternatively, VTT 212 may be dynamically changed when CA interconnect 206 is idle (and/or in response to other conditions).

In some embodiments, the amount of the offset is equal to or greater than the DC receiver margin of receivers 204. The term “DC receiver margin” refers to the uncertainty about the precise voltage levels needed to trip a receiver. This uncertainty is related to noise and other factors.

Host 110B includes VREF generation circuitry 218 to generate CA_VREF 208. In the illustrated embodiment, VREF generation circuitry 218 includes a voltage divider network ( e.g., variable resistors 214 and 216). In alternative embodiments, VREF generation circuitry 218 may be implemented differently.

In some embodiments, the values of variable resistors 214 and 216 may be set during a calibration process by, for example, circuits 114 (shown in FIG. 1). In alternative embodiments, the values of variable resistors 214 and 216 may be dynamically set by offset control logic (e.g., logic 102, shown in FIG. 1).

Driver 202 is a tri-state driver capable of tri-stating CA interconnect 206. In some embodiments, driver 202 symmetrically drives driver signal 210 around CA_VREF 208. The term “symmetrical” refers to driver signal 210 having (e.g., ±10%) equal swings above and below CA_VREF 208. In some embodiments, calibration circuitry 114 (shown in FIG. 1) calibrates CA driver 202 so that driver signal 210 is symmetrical around CA_VREF 208. For example, calibration circuitry 114 may set the pull up values of CA driver 202 to be greater than the pull down values.

In some embodiments, calibration circuit 114 may include a series transistor (e.g., in series with the N and P transistors of CA driver 202) having a voltage that can be varied to adjust the calibration setting. In alternative embodiments, calibration circuit 114 may be based on a digital implementation that includes a different number of pull up legs versus pull down legs that can be selectively activated to control the behavior of driver signal 210.

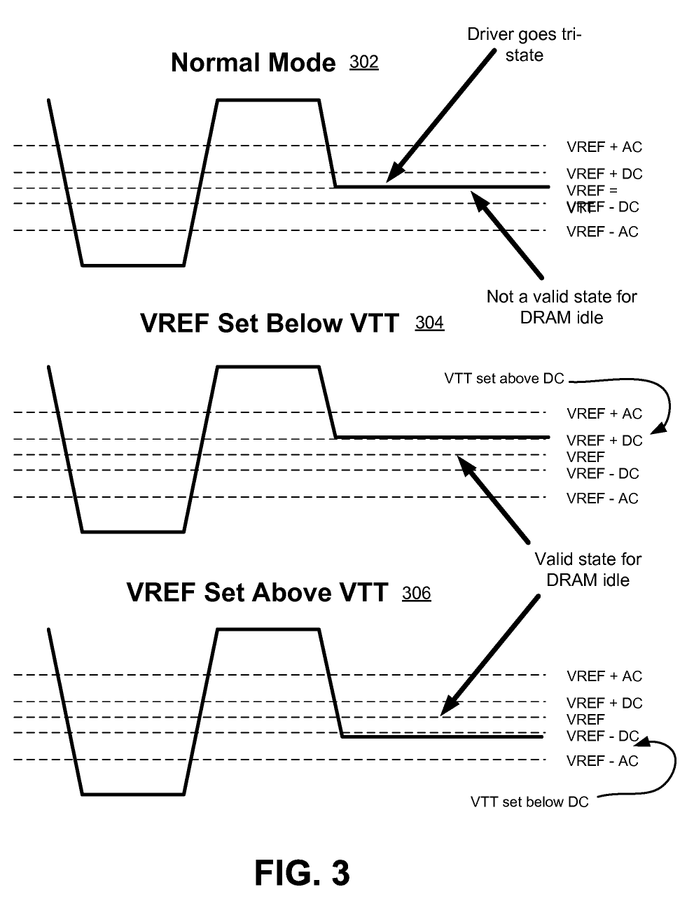

FIG. 3 is a signal diagram illustrating an offset between a reference voltage and a termination voltage, according to an embodiment of the invention. Normal mode (402) illustrates the case in which VREF is substantially equal to VTT when the CA driver (e.g., driver 202, shown in FIG. 2) goes tri-state. When operating in this mode, the CA lines are not in a valid state and the op amps on either side of the interconnect are consuming a significant amount of power. Diagram 404 illustrates the case in which VREF is offset below VTT by (at least) the DC receiver margin. Similarly, diagram 406 illustrates the case in which VREF is offset above VTT by (at least) the DC receiver margin. In both cases, the CA lines are in a valid state and the amount of power consumed by the op amps connected to the interconnect is reduced.

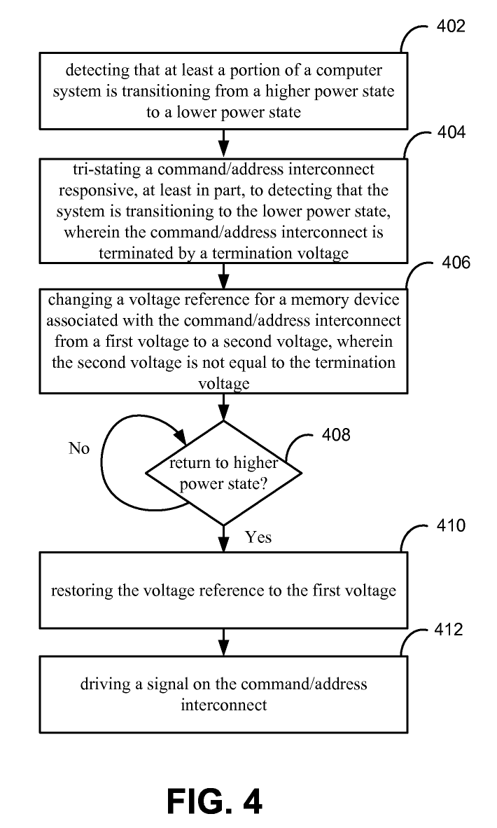

FIG. 4 is a flow diagram illustrating selected aspects of a method for a low power idle mode through reference offset, according to an embodiment of the invention. Referring to process block 402, a host (e.g., host 110 shown in FIG. 1) detects that at least portion of a computer is transitioning from a higher power state to a lower power state. For example, the host may detect that the system is entering a sleep, hibernate, or other power management state. In some embodiments, the host “detects” that the system is entering a low power state when it receives an associated command from a processor.

Referring to process block 404, the host tri-states the CA interconnect when it detects that the system is entering the lower power state. Tri-stating the CA interconnect refers to the drivers transitioning to an idle state. In addition, the host dynamically offsets the CA VREF from VTT at 406. For example, the host may dynamically set VREF from a first voltage (such as VDDQ/2) to a second voltage (such as VDDQ/2+offset). In alternative embodiments, the order of process blocks 404 and 406 may be reversed. In yet other alternative embodiments, process blocks 404 and 406 may occur at substantially the same time.

Referring to process block 408, the host detects that the system is returning to a higher power level. For example, the host may detect that the system is returning to an operational state (or a more fully operational state) from a sleep state (or another power management state).

The host restores the VREF to its previous value at 410. For example, the host may dynamically set VREF from a second voltage (such as VDDQ/2+offset) to a first voltage (such as VDDQ/2). The host drives a signal on the CA interconnect as shown by 412.

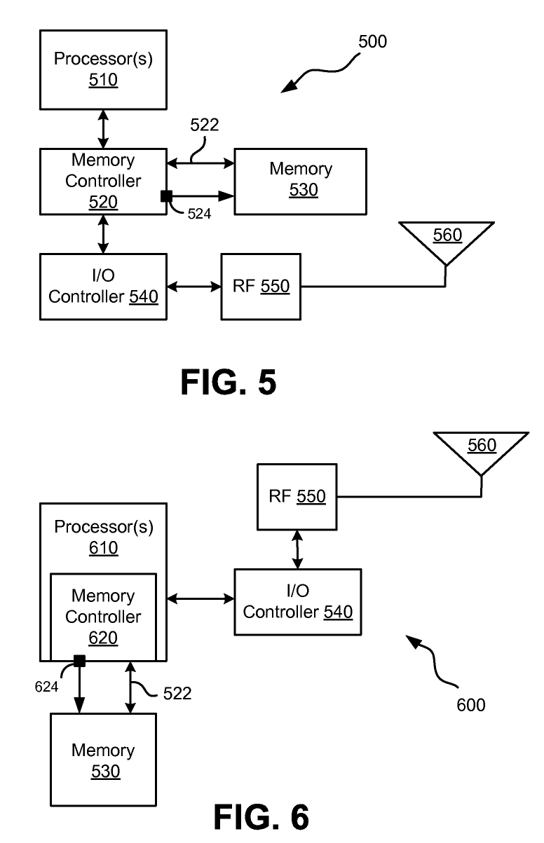

FIG. 5 is a block diagram illustrating selected aspects of an electronic system according to an embodiment of the invention. Electronic system 500 includes processor 510, memory controller 520, memory 530, input/output (IO) controller 540, radio frequency (RF) circuits 550, and antenna 560. In operation, system 500 sends and receives signals using antenna 560, and these signals are processed by the various elements shown in FIG. 5. Antenna 560 may be a directional antenna or an omni-directional antenna. As used herein, the term omni-directional antenna refers to any antenna having a substantially uniform pattern in at least one plane. For example, in some embodiments, antenna 560 may be an omni-directional antenna such as a dipole antenna or a quarter wave antenna. Also, for example, in some embodiments, antenna 560 may be a directional antenna such as a parabolic dish antenna, a patch antenna, or a Yagi antenna. In some embodiments, antenna 560 may include multiple physical antennas.

Radio frequency circuit 550 communicates with antenna 560 and IO controller 540. In some embodiments, RF circuit 550 includes a physical interface (PHY) corresponding to a communication protocol. For example, RF circuit 550 may include modulators, demodulators, mixers, frequency synthesizers, low noise amplifiers, power amplifiers, and the like. In some embodiments, RF circuit 550 may include a heterodyne receiver, and in other embodiments, RF circuit 550 may include a direct conversion receiver. For example, in embodiments with multiple antennas 560, each antenna may be coupled to a corresponding receiver. In operation, RF circuit 550 receives communications signals from antenna 560 and provides analog or digital signals to IO controller 540. Further, IO controller 540 may provide signals to RF circuit 550, which operates on the signals and then transmits them to antenna 560.

Processor(s) 510 may be any type of processing device. For example, processor 510 may be a microprocessor, a microcontroller, or the like. Further, processor 510 may include any number of processing cores or may include any number of separate processors.

Memory controller 520 provides a communication path between processor 510 and other elements shown in FIG. 5. In some embodiments, memory controller 520 is part of a hub device that provides other functions as well. As shown in FIG. 5, memory controller 520 is coupled to processor(s) 510, IO controller 540, and memory 530. In some embodiments, memory controller 520 (and/or memory controller 720, shown in FIG. 7) includes an additional electrical contact 524 (and/or 624) to provide a controllable CA VREF to memory 530. In some embodiments, the CA VREF is offset from the VTT on the receiver side. Memory controller 520 (and/or memory controller 720) may provide one or more driver signals to memory 530 that are symmetrical around CA VREF.

Memory 530 may include multiple memory devices. These memory devices may be based on any type of memory technology. For example, memory 530 may be random access memory (RAM), dynamic random access memory (DRAM), static random access memory (SRAM), nonvolatile memory such as FLASH memory, or any other type of memory.

Memory 530 may represent a single memory device or a number of memory devices on one or more modules. Memory controller 520 provides data through interconnect 522 to memory 530 and receives data from memory 530 in response to read requests. Commands and/or addresses may be provided to memory 530 through interconnect 522 or through a different interconnect (not shown). Memory controller 520 may receive data to be stored in memory 530 from processor 510 or from another source. Memory controller 520 may provide the data it receives from memory 530 to processor 510 or to another destination. Interconnect 522 may be a bi-directional interconnect or a unidirectional interconnect. Interconnect 522 may include a number of parallel conductors. The signals may be differential or single ended. In some embodiments, interconnect 522 operates using a forwarded, multiphase clock scheme.

Memory controller 520 is also coupled to IO controller 540 and provides a communications path between processor(s) 510 and IO controller 540. IO controller 540 includes circuitry for communicating with IO circuits such as serial ports, parallel ports, universal serial bus (USB) ports and the like. As shown in FIG. 5, IO controller 540 provides a communication path to RF circuits 550.

FIG. 6 is a bock diagram illustrating selected aspects of an electronic system according to an alternative embodiment of the invention. Electronic system 600 includes memory 630, IO controller 640, RF circuits 650, and antenna 660, all of which are described above with reference to FIG. 6. Electronic system 600 also includes processor(s) 610 and memory controller 620. As shown in FIG. 6, memory controller 620 may be on the same die as processor(s) 610. Processor(s) 610 may be any type of processor as described above with reference to processor 610 (FIG. 5). Example systems represented by FIGS. 5 and 6 include desktop computers, laptop computers, servers, cellular phones, personal digital assistants, digital home systems, and the like.

Elements of embodiments of the present invention may also be provided as a machine-readable medium for storing the machine-executable instructions. The machine-readable medium may include, but is not limited to, flash memory, optical disks, compact disks-read only memory (CD-ROM), digital versatile/video disks (DVD) ROM, random access memory (RAM), erasable programmable read-only memory (EPROM), electrically erasable programmable read-only memory (EEPROM), magnetic or optical cards, propagation media or other type of machine-readable media suitable for storing electronic instructions. For example, embodiments of the invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the description above, certain terminology is used to describe embodiments of the invention. For example, the term “logic” is representative of hardware, firmware, software (or any combination thereof) to perform one or more functions. For instance, examples of “hardware” include, but are not limited to, an integrated circuit, a finite state machine, or even combinatorial logic. The integrated circuit may take the form of a processor such as a microprocessor, an application specific integrated circuit, a digital signal processor, a micro-controller, or the like.

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of embodiments of the invention, various features are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed subject matter requires more features than are expressly recited in each claim. Rather, as the following claims reflect, inventive aspects lie in less than all features of a single foregoing disclosed embodiment. Thus, the claims following the detailed description are hereby expressly incorporated into this detailed description.

What is claimed is:

1. An integrated circuit comprising:
tri-state driver circuitry to generate a driver signal for a command/address interconnect of a double data rate (DDR) memory system, the tri-state driver circuitry capable of tri-stating the driver signal, wherein the command/address interconnect is terminated by a termination voltage; and
voltage reference generation circuitry to generate a voltage reference for the command/address interconnect, wherein the voltage reference is not equal to the termination voltage.

2. The integrated circuit of claim 1, wherein the voltage reference is substantially equal to VDDQ/2 and
further wherein the termination voltage is offset from the voltage reference by, at least, a receiver direct current (DC) margin.

3. The integrated circuit of claim 2, wherein the driver signal is substantially symmetrical about the voltage reference.

4. The integrated circuit of claim 1, wherein the termination voltage is substantially equal to VDDQ/2 and
the voltage reference is a controllable voltage reference, the controllable voltage reference to be offset from the termination voltage by, at least, a receiver DC margin.

5. The integrated circuit of claim 4, wherein the controllable voltage reference is to be dynamically offset from the termination voltage by, at least, a receiver DC margin if the command/address interconnect is idle.

6. The integrated circuit of claim 4, wherein the driver signal is substantially symmetrical about the voltage reference.

7. The integrated circuit of claim 1, wherein the integrated circuit comprises a memory controller.

8. The integrated circuit of claim 7, wherein the integrated circuit further comprises a processor.

9. A method comprising:
detecting, at a host, that at least a portion of a computer system is transitioning from a higher power state to a lower power state;
tri-stating a command/address interconnect responsive, at least in part, to detecting that the system is transitioning to the lower power state, wherein the command/address interconnect is terminated by a termination voltage; and
changing a voltage reference for a memory device associated with the command/address interconnect from a first voltage to a second voltage, wherein the second voltage is not equal to the termination voltage.

10. The method of claim 9, wherein the second voltage is offset from the termination voltage by, at least, a receiver direct current (DC) margin.

11. The method of claim 9, wherein the command/address interconnect is a double data rate (DDR) command/address interconnect.

12. The method of claim 9, further comprising:
detecting that at least a portion of the computer system is transitioning from the lower power state to the higher power state;
restoring the voltage reference to the first voltage; and
driving a signal on the command/address interconnect.

13. The method of claim 9, wherein the host includes a memory controller and the memory device includes a dynamic random access memory device (DRAM).

14. A system comprising:
a memory device; and
a host coupled with the memory device via a command/address interconnect, the host including,
tri-state driver circuitry to generate a driver signal for the command/address interconnect, the tri-state driver circuitry capable of tri-stating the driver signal, wherein the command/address interconnect is terminated by a termination voltage, and
voltage reference generation circuitry to generate a voltage reference for the command/address interconnect, wherein the voltage reference is not equal to the termination voltage.

15. The system of claim 14, wherein the voltage reference is substantially equal to VDDQ/2 and
further wherein the termination voltage is offset from the voltage reference by, at least, a receiver direct current (DC) margin.

16. The system of claim 15, wherein the driver signal is substantially symmetrical about the voltage reference.

17. The system of claim 14, wherein the termination voltage is substantially equal to VDDQ/2 and
the voltage reference is a controllable voltage reference, the controllable voltage reference to be offset from the termination voltage by, at least, a receiver DC margin.

18. The system of claim 17, wherein the controllable voltage reference is to be dynamically offset from the termination voltage by, at least, a receiver DC margin if the command/address interconnect is idle.

19. The system of claim 17, wherein the driver signal is substantially symmetrical about the voltage reference.

20. The system of claim 14, wherein the integrated circuit comprises a memory controller.
